(19) United States
(12) Patent Application Publication
(10) Pub. No.: US 2006/0099733 A1
(43) Pub. Date: May 11, 2006

(54) Semiconductor package and fabrication method

(76) Inventors: Frank S. Geefay, Cupertino, CA (US); Richard C. Ruby, Menlo Park, CA (US)

Correspondence Address: AGILENT TECHNOLOGIES, INC.;INTELLECTUAL PROPERTY ADMINISTRATION, LEGAL DEPT., P.O. BOX 7599, M/S DL429, LOVELAND, CO, 80537-0599, US

(21) Appl. No.: 10/985,312

(22) Filed: Nov. 9, 2004

(51) Int. Cl. H01L 21/44

(52) U.S. Cl. 438/106

(57) ABSTRACT

The present invention provides a first wafer and a second wafer having a device. A separation layer is formed on the first wafer. A cap is formed on the separation layer. The cap and the second wafer are bonded using a gasket. The first wafer is separated from the cap to form the semiconductor package comprised of the cap, the gasket, and the second wafer.

### BACKGROUND ART

The present invention relates generally to protecting semiconductor structures, and more particularly to a method and apparatus for protecting delicate air bridge structures. In recent years, mobile phones, lap top computers, and personal digital assistants have rapidly come into wide use. Consumers, eagerly embracing these new innovations, are quickly demanding higher performance, weight reduction, and miniaturization. Thus, technology for densely packing semiconductor devices, such as CPUs, microprocessors, and passive electronic components, is necessary.

One technological advance is the development of Multi-Chip Module (“MCM”) systems. In MCM systems a plurality of separately manufactured chips are densely mounted onto one module, with wiring lengths as short as possible.

MCM systems have many advantages. Included among these are light weight and small volume packaging. A further advantage is the short time required to design and fabricate a system using MCM circuits.

Design and fabrication time is saved in several ways. First, functionality can be quickly added without having to design a whole new integrated circuit. Secondly, MCM systems require minimal processing of substrates.

Substrates are a standard stock item, and a MCM system may only require the formation of cavities for the proper placement and alignment of semiconductor chips. If cavities are needed, they may be formed in the substrate by conventional straightforward processes, such as laser milling.

High performance semiconductor devices are often fabricated from gallium arsenide (“GaAs”). These high-speed devices may have delicate structures which can easily be damaged or destroyed during fabrication. For example, air bridge structures, which are bridges of metal suspended in air supported by posts, provide improved signal performance, but are quite vulnerable during fabrication.

### DISCLOSURE OF THE INVENTION

The present invention provides a first wafer and a second wafer having a device. A separation layer is formed on the first wafer. A cap is formed on the separation layer. The cap and the second wafer are bonded using a gasket. The first wafer is separated from the cap to form the semiconductor package comprised of the cap, the gasket, and the second wafer.

The present invention has advantages that will become apparent to those skilled in the art from a reading of the following detailed description when taken with reference to the accompanying drawings.

### BRIEF DESCRIPTION OF THE DRAWINGS

FIG. 1 is a cross-sectional view of a cap placement structure in accordance with an embodiment of the present invention;

FIG. 2 is the structure of FIG. 1 with the addition of a cap layer;

FIG. 3 is the structure of FIG. 2 with the addition of a gasket layer;

FIG. 4 is the structure of FIG. 3 with a cap structure;

FIG. 5 is a cross-sectional view of a multi-chip module substrate;

FIG. 6 is the structure of FIG. 5 with the addition of a photoresist;

FIG. 7 is the structure of FIG. 6 with the addition of a contact layer;

FIG. 8 is the structure of FIG. 7 after removal of the photoresist to create a gasket contact layer;

FIG. 9 is a simplified schematic of a cap transfer system;

FIG. 10 is the system of FIG. 9 during wafer bonding;

FIG. 11 is a protected air bridge with cap structure in accordance with an embodiment of the present invention; and

FIG. 12 is a flow chart of a method for manufacturing a semiconductor package in accordance with the present invention.

### BEST MODE FOR CARRYING OUT THE INVENTION

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

Likewise, the drawings showing embodiments of the device are semi-diagrammatic and not to scale and, particularly, some of the dimensions are for the clarity of presentation and are shown greatly exaggerated in the FIGs. In addition, where multiple embodiments are disclosed and described having some features in common, for clarity and ease of illustration, description, and comprehension thereof, like features one to another will ordinarily be described with like reference numerals.

The term “horizontal” as used herein is defined as a plane parallel to the conventional plane or surface of the wafer, regardless of its orientation. The term “vertical” refers to a direction perpendicular to the horizontal as just defined. Terms, such as “on”, “above”, “below”, “bottom”, “top”, “side” (as in “sidewall”), “higher”, “lower”, “over”, and “under”, are defined with respect to the horizontal plane.

The term “processing” as used herein includes deposition of material or photoresist, patterning, exposure, development, etching, cleaning, and/or removal of the material or photoresist as required in forming a described structure.

The term “air” is used herein to describe a generic gas and could include atmospheric air or inert gasses such as argon.

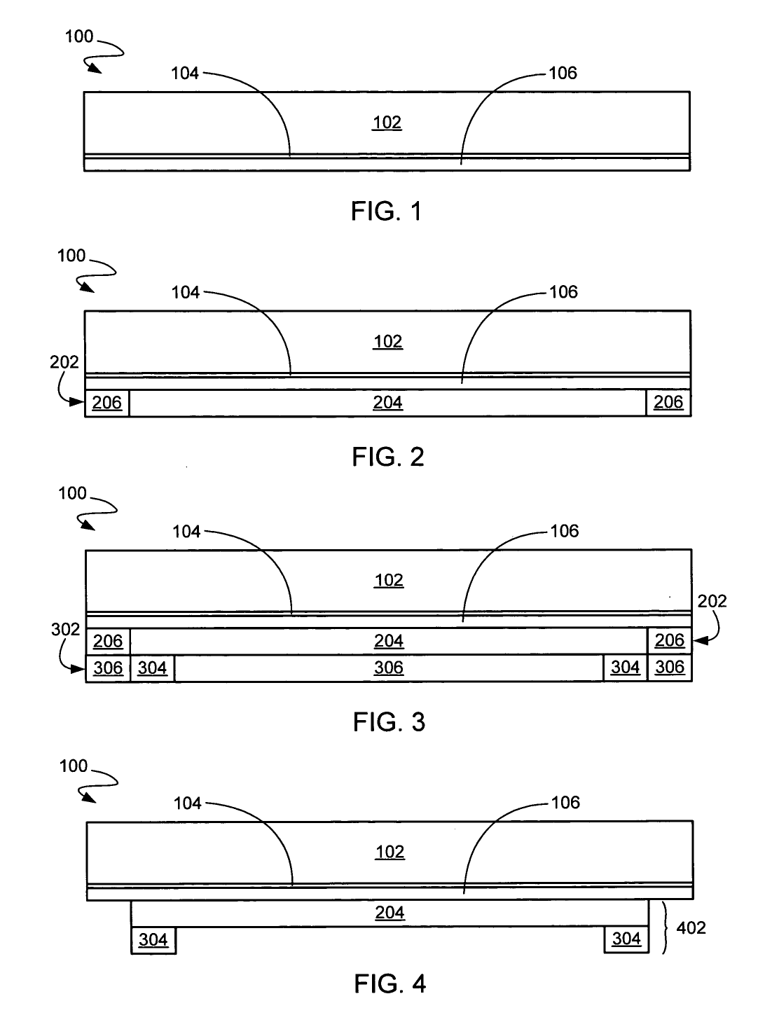

Referring now to FIG. 1, therein is shown a cross-sectional view of a cap placement structure 100 in accordance with an embodiment of the present invention. A reusable transfer wafer 102 is formed from alumina, sapphire, silicon, or GaAs. An adhesive layer 104, such as titanium, is formed on the reusable transfer wafer 102. Below the adhesive layer 104, a separation layer 106, such as gold, is formed on and adheres to the adhesive layer 104. Because gold has poor adhesion to most non-metallic materials such as silicon and alumina, the adhesive layer 104 is needed to adhere to the gold.

Referring now to FIG. 2, therein is shown the structure of FIG. 1 after further processing. A cap layer 202 of a photosensitive material, such as polyimide or benzocyclobutene (“BCB”), is dispensed onto the separation layer 106. Gold does not react well with polyimide or BCB. Thus, the adhesion of the cap layer 202 is at best marginal, but adequate enough to adhere to the separation layer 106.

The cap layer 202 is exposed to radiation, such as ultraviolet light, through a mask (not shown) using standard photolithographic processes. A post exposure bake initiates a reaction in the exposed portion of the cap layer 202, forming a cap 204 and an unexposed cap layer 206. The thickness of the cap 204 can vary with the particular application at hand, but is typically 10-50 μm thick.

Referring now to FIG. 3, therein is shown the structure of FIG. 2 after further processing. A gasket layer 302 of a photosensitive material, such as polyimide or BCB, is deposited onto the cap layer 202. The cap 204 does not dissolve into the gasket layer 302. The gasket layer 302 is exposed to radiation, such as ultraviolet light, through a mask (not shown) using standard photolithographic processes. A post exposure bake initiates a reaction in the exposed portion of the gasket layer 302, forming a gasket 304 and an unexposed gasket layer 306.

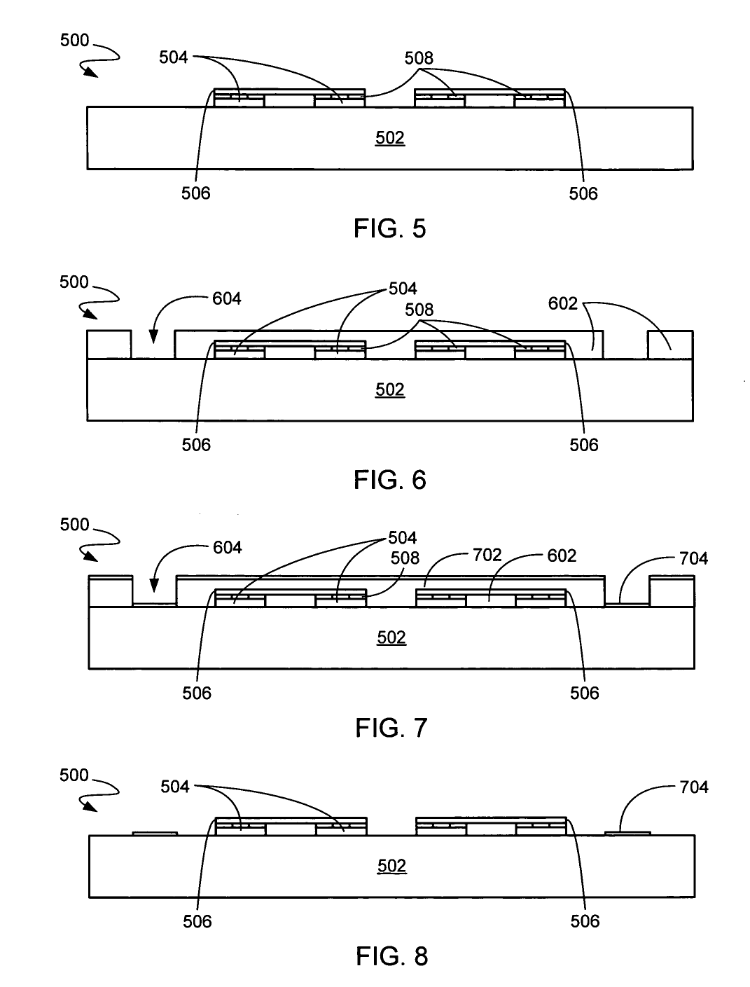

The gasket 304 must allow for some compression during wafer bonding (as further described with respect to FIG. 10) as well as shrinkage during curing (as further described with respect to FIG. 11). Therefore, in one embodiment the height of the gasket 304 is at least 1.5-2.5 times greater than the height of devices (not shown, but see the devices 504 in FIG. 5) that will be protected by the cap 204. Thus, the gasket 304 is dimensioned to adequately space the cap 204 above the devices.

Referring now to FIG. 4, therein is shown the structure of FIG. 3 after further processing. The unexposed cap layer 206 (FIG. 3) and the unexposed gasket layer 306 (FIG. 3) are removed through a conventional developing process. The cap 204 and the gasket 304 remain, thus forming a polyimide or BCB cap structure 402.

Referring now to FIG. 5, therein is shown a cross-sectional view of a multi-chip module (“MCM”) substrate 500. The MCM substrate 500 is a device wafer 502 formed from GaAs. Devices 504 are formed through standard semiconductor fabrication processes on the device wafer 502.

MCM systems, comprising one or more of the MCM substrates 500, have many advantages. Included among these are light weight and small volume packaging. A further advantage is the short time required to design and fabricate a system using the MCM substrates 500.

Design and fabrication time is saved in several ways. First, functionality can be quickly added without having to design a whole new integrated circuit. Secondly, MCM systems require minimal processing of the device wafers 502.

The device wafer 502 is a standard stock item, and a MCM system may only require the formation of cavities for the proper placement and alignment of the devices 504. If cavities are needed, they may be formed in the device wafer 502 by conventional straightforward processes, such as laser milling.

The devices 504 are often high performance and may be fabricated from gallium arsenide (“GaAs”). The devices 504 may also have delicate structures, which can easily be damaged or destroyed during fabrication. Air bridge structures are elevated above the devices 504 and separated by an air gap. One form of the air bridge structures 506 are bridges of metal suspended in air supported by posts 508 which make contact to the devices 504 and the wafer 502. The air bridge structures 506 are used to provide improved signal propagation and reduced capacitive coupling. Such air bridge structures 506 are typically quite vulnerable during fabrication.

Referring now to FIG. 6, therein is shown the structure of FIG. 5 after further processing. A photoresist 602 is formed through standard photolithographic processes over the device wafer 502, the air bridge structures 506, and the devices 504. The photoresist 602 is formed so that the device wafer 502 is free of the photoresist 602 in a gasket contact region 604. Thus the photoresist 602 defines the gasket contact region 604.

Referring now to FIG. 7, therein is shown the structure of FIG. 6 after further processing. A contact layer 702 is deposited on the photoresist 602 and on the device wafer 502 in the gasket contact region 604. The contact layer 702 forms a gasket contact layer 704 in the gasket contact region 604. The gasket contact layer 704 is an adhesive material, such as titanium, that has good adhesion properties to the gasket 304 (FIG. 3) and the device wafer 502.

The gasket contact layer 704 and the gasket 304 (FIG. 3) do not need to be continuous structures, for example a continuous ring, around the devices 504. The gasket contact layer 704 and the gasket 304 (FIG. 3) may be broken up into separate segments (not shown). If the device wafer 502 consists of a material with good adhesion properties with the gasket 304 (FIG. 3), the contact layer 702 may be omitted.

Referring now to FIG. 8, therein is shown the structure of FIG. 7 after further processing. The photoresist 602 (FIG. 7) is removed, for example with a solvent, leaving the gasket contact layer 704. In addition, the removal of the photoresist 602 (FIG. 7) lifts off the contact layer 702 (FIG. 7) and leaves the air bridge structures 506 intact.

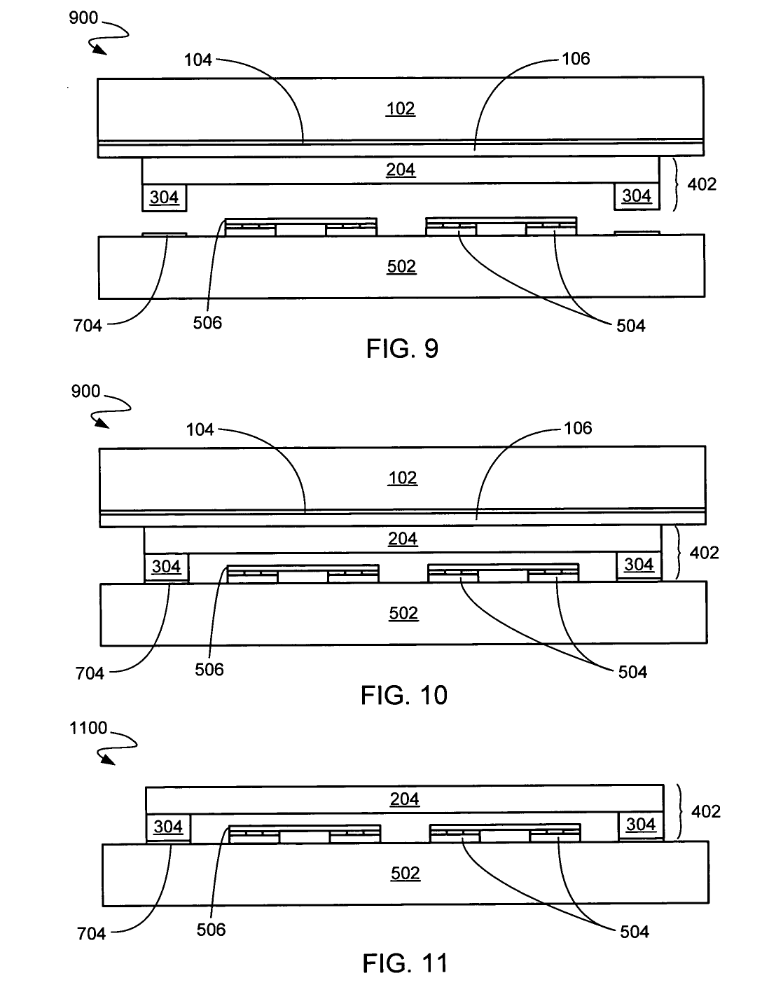

Referring now to FIG. 9, therein is shown a simplified schematic of a cap transfer system 900. The reusable transfer wafer 102 is aligned with the device wafer 502, such that the gasket 304 of the cap structure 402 is positioned above the gasket contact layer 704. The gasket 304 and the gasket contact layer 704 are shaped to have complementary dimensions. Thus, the gasket 304 on the reusable transfer wafer 102 faces the gasket contact layer 704 on the device wafer 502.

Referring now to FIG. 10, therein is shown the system of FIG. 9 during wafer bonding. The reusable transfer wafer 102 and the device wafer 502 are placed into a wafer bonding machine (not shown). Air is purged from the wafer bonding machine. An inert gas such as nitrogen is then pumped into the wafer bonding machine. The purging and pumping is repeated two to three times in order to reduce the amount of air and oxygen trapped under the cap 204.

The wafer bonding machine is then pumped down to about 500 mbar pressure to about 999 mbar pressure. For example, in one embodiment the wafer bonding machine was pumped down to about 500 mbar pressure. This reduces the ballooning of the cap 204 of the cap structure 402 during high temperature processing. In addition the partial vacuum may assist bonding by causing the cap structure 402 to act as a suction cup.

The reusable transfer wafer 102 and the device wafer 502 are brought together until the gasket 304 of the cap structure 402 contacts the gasket contact layer 704. The wafer bonding machine quickly heats the joined reusable transfer wafer 102 and the device wafer 502 to about 18° C. to about 500° C. For example, in one embodiment the wafer bonding machine heated the joined reusable transfer wafer 102 and the device wafer 502 to about 250° C. The reusable transfer wafer 102 and the device wafer 502 are then firmly pressed together with about 1 N to about 40 kN of force on wafers for about one minute to about two hours. For example, in one embodiment about 1500 N of force was used on 4 inch wafers for about ten minutes. Thus the gasket 304 of the cap structure 402 and the gasket contact layer 704 are bonded and may be hermetically sealed. After removing the force, the bonded reusable transfer wafer 102 and device wafer 502 are allowed to cool and are removed from the wafer bonding machine.

Referring now to FIG. 11, therein is shown a protected air bridge with cap structure 1100 fabricated as just described in accordance with an embodiment of the present invention. After cooling and removal from the wafer bonding machine, the reusable transfer wafer 102 (FIG. 10) is carefully pried apart and removed from the device wafer 502. The cap structure 402 adheres much better to titanium than to gold. Thus, the cap structure 402 remains attached to the device wafer 502 and separates from the reusable transfer wafer 102 (FIG. 10) during the prying and removal thereof. The reusable transfer wafer 102 (FIG. 10) may now be reused.

The protected air bridge with cap structure 1100 is then heat treated to cure the cap structure 402. The cap structure 402 completely covers and encloses the devices 504 and the air bridge structures 506. The cap structure 402 provides a protective cover over the delicate air bridge structures 506 and the devices 504. Thus, the cap structure 402 allows the delicate air bridge structures 506 and the devices 504 to be placed into a conventional molded plastic package configuration (not shown), protected from the intrusion of plastic package compound (not shown) into the sensitive air bridge structures 506.

The cap structure 402 may be placed to protect selected delicate structures, such as the air bridge structures 506, and/or the devices 504. In addition, the cap structure 402 may cover an entire die (not shown) including all structures and devices.

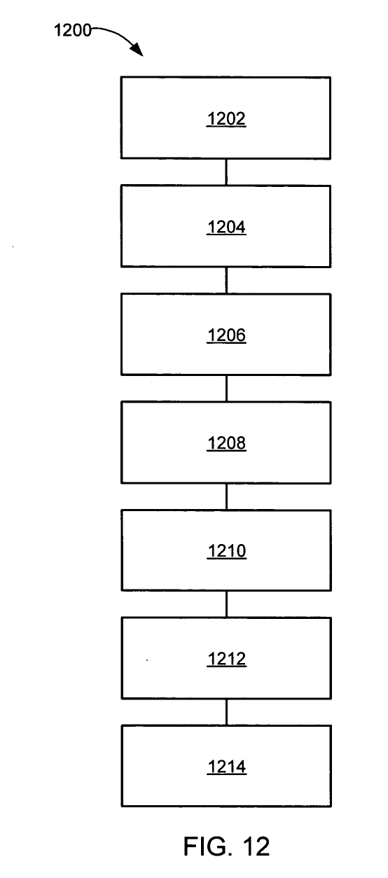

Referring now to FIG. 12, therein is shown a flow chart of a method 1200 for manufacturing a semiconductor package in accordance with the present invention. The method 1200 includes providing a first wafer in a block 1202; providing a second wafer having a device in a block 1204; forming a separation layer on the first wafer in a block 1206; forming a cap on the separation layer in a block 1208; bonding the cap and the second wafer using a gasket in a block 1210; and separating the first wafer from the cap to form the semiconductor package comprised of the cap, the gasket, and the second wafer in a block 1214.

Thus, it has been discovered that the semiconductor package method and apparatus of the present invention furnish important and heretofore unknown and unavailable solutions, capabilities, and functional advantages for protecting devices and air bridge structures. The resulting processes and configurations are straightforward, economical, uncomplicated, highly versatile and effective, and can be implemented by adapting known components for ready manufacturing, application, and utilization.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations which fall within the scope of the included claims. All matters hithertofore set forth herein or shown in the accompanying drawings are to be interpreted in an illustrative and non-limiting sense.

The invention claimed is:

1. A method for manufacturing a semiconductor package, comprising:
providing a first wafer;
providing a second wafer having a device;
forming a separation layer on the first wafer;
forming a cap on the separation layer;
bonding the cap and the second wafer using a gasket; and
separating the first wafer from the cap to form the semiconductor package comprised of the cap, the gasket, and the second wafer.

2. The method of claim 1 further comprising forming an adhesive layer on the first wafer.

3. The method of claim 1 wherein forming the separation layer uses gold.

4. The method of claim 1 wherein:
forming the cap uses photosensitive material; and
forming the gasket uses photosensitive material.

5. The method of claim 1 wherein bonding the cap and the second wafer further comprises:
forming a gasket contact layer on the second wafer;
bonding the gasket and the gasket contact layer; and
separating the first wafer from the cap to form the semiconductor package comprised of cap, the gasket, the gasket contact layer, and the cap on the second wafer.

6. The method of claim 1 wherein bonding the cap and the second wafer further comprises:
heating the gasket and the second wafer to about 18° C. to about 500° C.; and
pressing together the gasket and the second wafer with about 1 N to about 40 kN of force for about one minute to about two hours.

7. The method of claim 1 wherein bonding the gasket and the gasket contact layer further comprises pressing together the gasket and the gasket contact layer in about 500 mbar pressure to about 999 mbar pressure.

8. A method for manufacturing a semiconductor package, comprising:
providing a reusable first wafer;
providing a second wafer having devices and air bridge structures;
forming an adhesive layer on the reusable first wafer;
forming a separation layer on the adhesive layer;
forming a cap structure on the separation layer, the cap structure having a height greater than the height of the devices, by:
depositing a cap layer on the separation layer;
hardening the cap layer into a cap;
depositing a gasket layer on the cap; and
hardening the gasket layer into a gasket;
forming a photoresist defining a gasket contact region on the second wafer;
forming a gasket contact layer in the gasket contact region;
removing the photoresist;
bonding the cap structure and the gasket contact layer; and
separating the reusable first wafer from the cap structure to leave the cap structure attached to the gasket contact layer on the second wafer.

9. The method of claim 8 wherein:
providing the reusable first wafer uses alumina, sapphire, silicon, or GaAs;
forming the cap structure further comprises forming the cap structure to enclose the devices and the air bridge structures; and
depositing the adhesive layer uses titanium.

10. The method of claim 8 wherein depositing the separation layer uses gold.

11. The method of claim 8 wherein:
depositing the cap layer uses polyimide or benzocyclobutene; and
depositing the gasket layer uses polyimide or benzocyclobutene.

12. The method of claim 8 wherein forming the gasket contact layer uses titanium.

13. The method of claim 8 wherein bonding the cap structure and the gasket contact layer further comprises:
heating the cap structure and the gasket contact layer to about 250° C.; and
pressing together the cap structure and the gasket contact layer with about 1500 N of force on 4 inch wafers for about ten minutes.

14. The method of claim 8 wherein bonding the cap structure and the gasket contact layer further comprises pressing together the cap structure and the gasket contact layer with about 500 mbar pressure.

15. A semiconductor package, comprising:
a wafer;
a device on the wafer;
a photosensitive gasket on the wafer; and
a photosensitive cap on the photosensitive gasket spaced from the device.

16. The semiconductor package of claim 15 wherein:
the photosensitive cap further comprises a polyimide or benzocyclobutene cap; and
the photosensitive gasket further comprises a polyimide or benzocyclobutene gasket.

17. The semiconductor package of claim 15 wherein the photosensitive gasket on the wafer further comprises:
a gasket contact layer on the wafer; and
the photosensitive gasket on the gasket contact layer.

18. The semiconductor package of claim 15 wherein:
the photosensitive cap and the photosensitive gasket comprise a cap structure; and
the height of the cap structure is 1.5 to 2.5 times the height of the device.

19. The semiconductor package of claim 15:
wherein the photosensitive cap and the photosensitive gasket comprise a cap structure; and
further comprising an inert gas under the cap structure.

20. The semiconductor package of claim 15 wherein the cap is 10 to 50 μm thick.
